(19) United States
(12) Patent Application Publication
(10) Pub. No.: US 2020/0076412 A1
(43) Pub. Date: Mar. 5, 2020

(54) DUTY CYCLE CORRECTION FOR COMPLEMENTARY CLOCK SIGNALS

(71) Applicant: SanDisk Technologies LLC, Addison, TX (US)

(72) Inventors: Srinivas Rajendra, Milpitas, CA (US); Tianyu Tang, Milpitas, CA (US); Venkatesh Ramachandra, San Jose, CA (US)

(73) Assignee: SanDisk Technologies LLC, Addison, TX (US)

(21) Appl. No.: 16/206,321

(22) Filed: Nov. 30, 2018

Related U.S. Application Data
(60) Provisional application No. 62/725,843, filed on Aug. 31, 2018.

(51) Int. Cl. H03K 5/156; H03K 5/134; G11C 7/22; G11C 11/4076; H01L 27/11524

(52) U.S. Cl. CPC H03K 5/1565; H03K 5/134; H01L 27/11524; G11C 11/4076; G11C 7/222

(57) ABSTRACT

A duty cycle correction circuit includes an AND/OR logic circuit that reduces duty cycle distortion in a pair of input signals. The AND/OR logic circuit includes a first push-pull circuit configured to generate a first output signal in response to receipt of a first pair of delayed input signals, and a second push-pull circuit configured to generate a second output signal in response to receipt of a second pair of delayed input signals. The first and second push-pull circuits may have matching beta ratios. Additionally, a latch is coupled to output nodes of the first and second push-pull circuits. The latch is configured to maintain magnitude levels at the output nodes during delay offset periods of the first and second pairs of delayed input signals.

### CROSS-REFERENCE TO RELATED APPLICATION

This application claims the benefit of U.S. Provisional Application No. 62/725,843, filed Aug. 31, 2018. The contents of U.S. Provisional Application No. 62/725,843 are incorporated by reference in their entirety.

### BACKGROUND

In electronic systems, a first circuit may send a clock signal to a second circuit, and the second circuit may use the clock signal to perform certain actions. For example, in memory systems, to perform a write operation, the first circuit may send a clock signal along with one or data signals, and the second circuit may use the clock signal to identify the voltage levels or data values of the data carried by the data signals. In addition, to perform a read operation, the first circuit may send a clock signal to the second circuit, and the second circuit may use the clock signal to retrieve data it is storing and send the data to the first circuit.

To minimize the amount of errors between the first and second circuits when they communicate, it is desirable for the second circuit to receive the clock signal having a duty cycle at a target duty cycle level, which is typically 50%. However, in actual implementation the second circuit receives the clock signal with duty cycle distortion. To correct for the distortion, the second circuit includes a duty cycle correction circuit that reduces the amount of distortion by moving the duty cycle from an initial level toward the target duty cycle level.

In some configurations, the duty cycle correction circuit itself undesirably introduces duty cycle distortion into the signals it generates, degrading its overall ability to eliminate duty cycle distortion. Accordingly, duty cycle correction circuits that introduce or add no or minimal duty cycle distortion are desirable.

### BRIEF DESCRIPTION OF THE DRAWINGS

The accompanying drawings, which are incorporated in and constitute a part of this specification illustrate various aspects of the specification and together with the description, serve to explain its principles. Wherever convenient, the same reference numbers will be used throughout the drawings to refer to the same or like elements.

FIG. 1 is a block diagram of an example system that includes a data requesting integrated circuit and a data retrieving integrated circuit.

FIG. 2 is an example timing diagram of a waveform of a data signal.

FIG. 3 is a block diagram of an example duty cycle correction circuit.

FIG. 4A is a timing diagram of an example pair of delayed clock signals that do not have a delay offset between them.

FIG. 4B is a timing diagram of an example pair of delayed clock signals that have a non-zero delay offset between them.

FIG. 5 are timing diagrams of a two pairs of delayed input signals and a pair of output signals, illustrating duty cycle correction through performance of AND and OR logical operations.

FIG. 6 is a circuit diagram of an example configuration of an AND/OR logic circuit of FIG. 3.

FIG. 7 is a partial circuit diagram of another example configuration of the AND/OR logic circuit of FIG. 3.

FIG. 8 is an example memory system including one or more duty cycle correction circuits.

### DETAILED DESCRIPTION

The present description describes circuits, apparatuses, devices, systems, and methods for correcting duty cycle distortion with an AND/OR logic circuit that performs AND and OR logical operations with matching beta ratios. In a first embodiment, a circuit includes a first push-pull, a second push-pull circuit, and a latch circuit. The first push-pull circuit is configured to generate a first output signal in response to receipt of a first pair of input signals. The second push-pull circuit is configured to generate a second output signal in response to receipt of a second pair of input signals. The latch circuit is coupled between the first push-pull circuit and the second push-pull circuit, and is configured to maintain magnitude levels of the first output signal and the second output signal during delay offset periods of the first pair of input signals and the second pair of input signals.

In some embodiments, the first push-pull circuit and the second push-pull circuit include matching beta ratios.

In some embodiments, the first push-pull circuit includes a NOR logic circuit that includes a parallel transistor branch disconnected from an output node at which the first push-pull circuit generates the first output signal.

In some embodiments, the parallel transistor branch includes an n-channel metal-oxide semiconductor field-effect transistor that includes a drain terminal and a source terminal coupled together.

In some embodiments, the second push-pull circuit includes a NAND logic circuit that includes a parallel transistor branch disconnected from an output node at which the second push-pull circuit generates the second output signal.

In some embodiments, the parallel transistor branch comprises a p-channel metal-oxide semiconductor field-effect transistor comprising a drain terminal and a source terminal coupled together.

In some embodiments, the latch circuit includes a pair of cross-coupled inverters.

In some embodiments, a first signal of the first pair of input signals and a second signal of the second pair of input signals are a pair of complementary signals.

In another embodiment, a circuit includes an AND/OR logic circuit configured to: receive a first pair of input signals and a second pair of input signals; generate a first signal of a pair of output signals according to AND logic on the first pair of input signals and a first beta ratio; and generate a second signal of the pair of output signals according to OR logic on the second pair of input signals and a second beta ratio that matches the first beta ratio.

In some embodiments, the AND/OR logic circuit is configured to maintain magnitude levels of the pair of output signals during delay offset periods of the first pair of input signals and the second pair of input signals.

In some embodiments, the AND/OR logic circuit includes a first push-pull circuit and a second push-pull circuit that are configured to float relative to a pair of output nodes during the delay offset periods.

In some embodiments, the first push-pull circuit includes the first beta ratio, the second push-pull circuit includes the second beta ratio, and the first beta ratio and the second beta ratio are constant values independent of a delay offset between the first pair of input signals or the second pair of input signals.

In some embodiments, the AND/OR logic circuit is configured to reduce duty cycle distortion in the first pair of input signals and the second pair of input signals in response to generation of the pair of output signals.

In some embodiments, the AND logic comprises NAND logic.

In some embodiments, the OR logic comprises NOR logic.

In another embodiment, a system includes a delay circuit, an AND/OR logic circuit, and a latch circuit. The delay circuit is configured to delay an input clock signal based on an amount of duty cycle distortion in the input clock signal to generate a delayed input clock signal. The AND/OR logic circuit includes a NOR logic circuit and a NAND logic circuit. The NOR logic circuit includes a first parallel transistor branch disconnected from a first output node, and is configured to generate a first output clock signal at the first output node in response to receipt of the input clock signal and the delayed input clock signal. The NAND logic circuit includes a second parallel transistor branch disconnected from a second output node, and is configured to generate a second output clock signal at the second output node in response to receipt of a complementary input clock signal and a complementary delayed input clock signal. The latch circuit is connected to the first output node and to the second output node.

In some embodiments, the NOR logic circuit includes a first beta ratio and the NAND logic circuit includes a second beta ratio that matches the first beta ratio.

In some embodiments, the first beta ratio of the NOR logic circuit is a fixed value independent of a delay offset between the first input clock signal and the first delayed input clock signal.

In some embodiments, the second beta ratio of the NAND logic circuit is a fixed value independent of a delay offset between the second input clock signal and the second delayed input clock signal.

In some embodiments, the latch includes a pair of cross-coupled inverters.

Other embodiments are possible, and each of the embodiments can be used alone or together in combination. Accordingly, various embodiments will now be described with reference to the attached drawings.

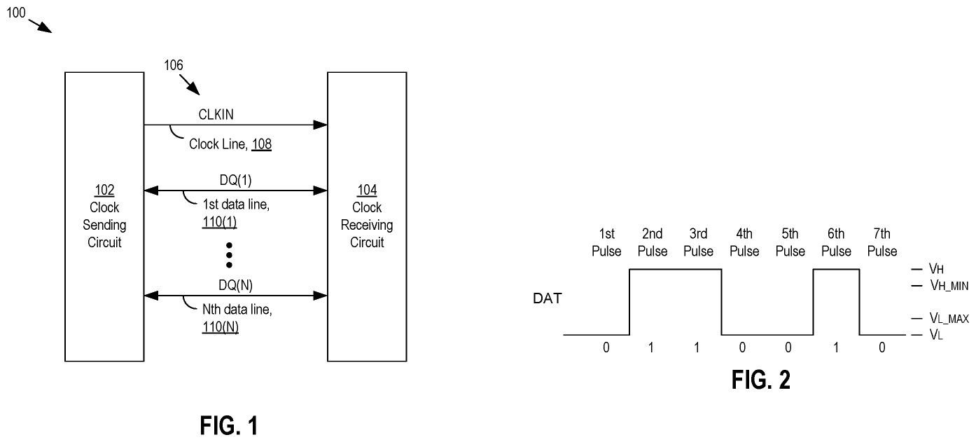

FIG. 1 shows a system 100 in which a duty cycle correction circuit may be implemented. The system 100 may include a clock sending circuit 102 and a clock receiving circuit 104 configured to communicate with each other via a communications bus 106. In particular example configurations, both the clock sending circuit 102 and the clock receiving circuit 104 are transceiver circuits, meaning that each can be configured to transmit and receive signals. For simplicity, the clock sending circuit 102 is the circuit in the system 100 that sends a clock signal, and the clock receiving circuit 104 is the circuit in the system 100 that receives the clock signal from the clock sending circuit 102 and corrects for duty cycle distortion in the received clock signal.

In some example configurations, the clock sending circuit 102 and the clock receiving circuit 104 form a source synchronous system. In general, a source synchronous system is a system in which a source circuit sends a data signal along with a clock signal to a destination circuit in order for the destination circuit to use the clock signal to identify the data values of the data signal. In the system 100, the clock sending circuit 102 and the clock receiving circuit 104 function as the source circuit and the destination circuit, and may change roles as the source circuit and the destination circuit in the source synchronous system, depending on whether they are performing a data-in operation or a data-out operation. For data-in operations, the clock sending circuit 102 sends data in the form of data signals to the clock receiving circuit 104. For these operations, the clock sending circuit 102 is the source circuit and the clock receiving circuit 104 is the destination circuit. The clock receiving circuit 104 identifies the data values of the data signals using the clock signal, such as in response to rising and/or falling edges of the clock signal. For data-out operations, the clock receiving circuit 104 sends data in the form of data signals to the clock sending circuit 102. For these operations, the data receiving circuit 104 is the source circuit and the clock sending circuit 102 is the destination circuit of the source synchronous system.

In a particular example configuration, as shown in FIG. 1, the communications bus 106 includes a clock line 108, and an N-number of data lines 110, extending from a first data line 110(1) to an Nth data line 110(N). In some example configurations, the clock line 108 is a unidirectional line, and the data lines 110 are bidirectional lines. Herein a unidirectional line is a transmission line that is configured to communicate signals one way or in one direction, either only from the clock sending circuit 102 to the clock receiving circuit 104, or only from the clock receiving circuit IC 104 to the clock sending circuit 102. Also, as used herein, a bidirectional line is a transmission line that is configured to communicate signals both ways or in both directions, from the clock sending circuit 102 to the clock receiving circuit 104, and from the clock receiving circuit 104 to the clock sending circuit 102. With reference to the configuration in FIG. 1, the clock line 108 communicates clock signals from the data requesting IC 102 to the data retrieving IC 104. Also, although not shown in FIG. 1, for some example configurations, the system 100 may include an additional clock line or an additional pair of clock lines. The clock receiving circuit 104 may be configured to output a clock signal (or a pair of complementary clock signals) on those additional clock line(s) when outputting the data signal(s) to the clock sending circuit 102.

The clock sending circuit 102 and the clock receiving circuit 104 communicate input and output signals between each other over the clock and data lines 108, 110 of the communications bus 106. The input and output signals include input clock signals, input data signals, output clock signals, and output data signals. The terms output and input are used herein to indicate the direction in which a signal is communicated between the clock sending circuit 102 and the clock receiving circuit 104. An input signal is a signal that a circuit receives on a line of a communications bus, and an output signal of a circuit is a signal that the circuit outputs onto a line of the communications bus. Of course, the terms input and output are relative terms that depend on the perspective of the circuit. An output signal that one circuit outputs can be an input signal for another circuit.

Herein, the input and output signals are identified with reference to (or from the perspective of) the clock receiving circuit 104. The clock sending circuit 102 sends an input clock signal CLKIN on the clock line 108 to the clock receiving circuit 104. The clock line 108 is shown in FIG. 1 as a single-ended transmission line that communicates a single-ended input clock signal CLKIN from the clock sending circuit 102 to the clock receiving circuit 104. In other example configurations, the clock line 108 is configured as a pair of clock lines configured to communicate a pair of complementary input clock signals CLKIN, CLKINb from the data requesting IC 102 to the data retrieving IC 104.

Additionally, for data-in operations, the clock sending circuit 102 sends data signals DQ(1) to DQ(N) on the data lines 110 to the clock receiving circuit 104. For data-out operations, the clock receiving circuit 104 sends data signals DQ(1) to DQ(N) on the data lines 110 to the clock sending circuit 102.

In general, a signal may be at a level at a given point in time. As used herein, a level of a signal at a given point in time is a magnitude value, such as a voltage magnitude value or a current magnitude value. In some cases, the signal may be referred to as being at a high level or at a low level, transitioning between a high level and a low level, or transitioning between a low level and a high level. In general, a high level and a low level are both magnitude values, where the high level is higher in magnitude than the low level. A high level of a signal may be a single high level, a level that is within a set or range of high levels, a maximum high level or a minimum high level of a set or range of high levels, or an average high level of a set or range of high levels. Similarly, a low level of a signal may be a single low level, a level that is within a set or range of low levels, a maximum low level or a minimum low level of a set or range of low levels, or an average low level of a set or range of low levels.

In addition or alternatively, a high level of a signal is a level that is at or above a minimum high level V_{H}_{_{_}}_{MIN}, and a low level of the signal is a level that is at or below a maximum low level V_{L}_{_{_}}_{MAX}. The minimum high level V_{H}_{_{_}}_{MIN} and the maximum low level V_{L}_{_{_}}_{MIN} may be predetermined levels or values, and in particular example configurations, predetermined levels or values specified as part of a swing requirement with which the source circuit 102 is configured to comply when transmitting the signal. A signal that transitions according to and/or in compliance with the swing requirement transitions to a high level that is at or above the minimum high level V_{H}_{_{_}}_{MIN} of the swing requirement, and transitions to a low level that is at or below the maximum low level V_{L}_{_{_}}_{MAX} of the swing requirement.

In general, a signal performs transitions between its high level and its low level. A given transition of a signal may be one of two transition types, including a rising transition and a falling transition. A signal performs a rising transition when the signal transitions from its low level to its high level, and performs a falling transition when the signal transitions from its high level to its low level.

A portion of a magnitude waveform of a signal over a transition is referred to as an edge. In particular, a portion of the magnitude waveform over a rising transition is a rising edge and a portion of the magnitude waveform over a falling transition is a falling edge.

Also, a clock signal, such as the input clock signal CLKIN, is a signal that has repetitive cycles occurring over successive periods T. Within each period T, a first portion of a respective cycle occurs first in time and a second portion of the respective cycle occurs second in time—i.e., after the first portion. After the second portion of one cycle occurs, the first portion of a next cycle occurs. Within a cycle, one of the portions is at a high level and the other portion is at a low level. Accordingly, the portions may be defined by consecutive rising and falling transitions or edges of the clock signal. For example, a given rising edge or a given falling edge may define or mark a boundary when one portion ends and a next portion, either of the same cycle or a next cycle, begins.

In addition, a clock signal may include clock pulses that are formed or defined by the rising and falling edges of the clock signal. In particular example configurations, the clock pulses of a clock signal correspond to the high level of the clock signal, in that each clock pulse is defined by a rising edge followed by a period where the clock signal is at its high level, and then followed by a falling edge. A pulse width of a given clock pulse is a time duration extending from a time that the magnitude of the rising edge of the clock pulse is at or rises to a predetermined level (e.g., 50% of the high level) to a time that the magnitude of the falling edge of the clock pulse is at or falls to the predetermined level. The clock pulses of the clock signal may occur according to the frequency of the clock signal.

In addition, a clock signal has an associated duty cycle. As used herein, a duty cycle of a clock signal is the percentage or fraction of one period that the clock signal is at its high level. In addition or alternatively, the duty cycle of a clock signal is the ratio of a pulse width of a clock pulse in a single period or cycle of the clock signal to a total time duration of the period or cycle.

Also, two signals of a pair of signals are complementary in that when one of the signals is at an associated high level the other is at an associated low level. The waveforms of two complementary signals are considered to inversely track each other in that when one signal performs a rising transition, the other signal performs a falling transition. In addition or alternatively, two signals that are complementary are 180-degrees out of phase with each other or have waveforms representative of two signals that are 180-degrees out of phase with each other.

For a pair of complementary signals, when a first signal of the pair is performing a rising transition, a second signal of the pair is performing a falling transition, or in the event that the rising and falling transitions are not occurring concurrently, then the transition of the second signal that is occurring closest in time to the rising transition of the first signal is a falling transition. Similarly, when the first signal of the pair is performing a falling transition, the second signal is performing a rising transition, or in the event that the rising and falling transitions are not occurring concurrently, then the transition of the second signal that is occurring closest in time to the falling transition of the first signal is a rising transition.

Additionally, a data signal is a signal that carries and/or includes data. The data carried by and/or included in a data signal includes a bit sequence of bits, where each bit includes or has a single-bit logic value of “1” or “0”. The data signal may include a series or sequence of data pulses corresponding to a bit sequence of the data. A data pulse is a portion of the magnitude waveform of the data signal that represents one or more bits of the bit sequence. Each data pulse may be at a level that indicates a data value, otherwise referred to as a logic level or a logic value. In addition, each data value is represented by a binary number or a binary value that includes one or more digits corresponding to and/or representing the one or more bits of the bit sequence. A duration of a data pulse is an amount of time that the level of the data pulse indicates the data value that the data pulse represents.

FIG. 2 shows a timing diagram of a magnitude waveform of at least a portion of an example data signal DAT, which may be representative of at least a portion of one of the N-number of data signals DQ(1) to DQ(N), or an internal data signal generated and/or communicated within the clock sending circuit 102 or the clock receiving circuit 104. For purposes of illustration, the example data signal DAT shown in FIG. 2 includes seven data pulses. Each data pulse is shown as being either at a high level at or above a minimum high level V_{H}_{_{_}}_{MIN} or at a low level at or below a maximum low level V_{L}_{_{_}}_{MAX}. For the example data signal DAT in FIG. 2, the high level and the low level each indicate a single-bit logic or data value of “1” or “0”, where the high level corresponds to and/or indicates a single-bit logic or data value of “1” (otherwise referred to as a logic 1 value) and the low level corresponds to and/or indicates a single-bit logic or data value of “0” (otherwise referred to as a logic 0 value). Other example data signals where different levels of the magnitude waveform correspond to and/or indicate multi-bit logic values (i.e., logic values that each include two or more digits or bits) may be possible.

For two consecutive data pulses of the data signal DAT, where the two consecutive pulses correspond to different logic levels, the data signal DAT performs a rising transition or a falling transition to transition between the two consecutive data pulses. For the example shown in FIG. 2, where one pulse in the sequence indicates a logic 0 value and a next pulse in the sequence indicates a logic 1 value, the data signal DAT performs a rising transition to transition between the first and second pulses. On the other hand, where one pulse corresponds to a logic 1 value and a next pulse indicates a logic 0 value, the data signal DAT performs a falling transition to transition between the first and second pulses. In addition, where two consecutive pulses indicate the same logic level, then as the pulse sequence transitions from the first data pulse to the next data pulse, the level of the data signal DAT stays the same during those two pulses, and a rising transition or a falling transition may not occur.

Referring back to FIG. 1, the clock receiving circuit 104 may receive the input clock signal CLKIN in order to perform various actions or functions. For example, during data-in operations where the clock receiving circuit 104 is receiving data signals DQ concurrently or in parallel with the input clock signal CLKIN, the clock receiving circuit 104 may determine when to identify or sample the voltage levels of the data signals DQ based on or using the input clock signal CLKIN. In particular, the clock receiving circuit 104 may determine to identify or sample the voltage levels in response to detecting sampling transitions, which may be rising transitions and/or falling transitions, of the input clock signal CLKIN. As another example during data-out operations where the clock receiving circuit 104 is to send data signals DQ to the clock sending circuit 102, the clock receiving circuit 104 may use the input clock signal CLKIN to retrieve data it is storing and/or to generate an output clock signal CLKOUT (not shown in FIG. 1) that it outputs concurrently or in parallel with the data signals DQ it sends to the clock sending circuit 102. In turn, the clock sending circuit 102 may use the output clock signal CLKOUT to identify or sample the voltage levels of the data signals DQ received from the clock receiving circuit 104.

Although not shown in FIG. 1, the clock receiving circuit 104 may include one or more internal circuit components, each configured to perform an action or function of the clock receiving circuit 104. To perform its action or function, an internal circuit component may directly receive the input clock signal CLKIN, or instead, may receive an internal clock signal that the clock receiving circuit 104 internally generates. In general, an internal clock of a circuit is a clock signal that the circuit internally generates independent or without receipt of another clock signal, such through use of an electronic oscillator, such as a voltage-controlled oscillator (VCO), for example; or is a clock signal that the circuit generates dependent on or in response to receipt of another clock signal. Accordingly, an internal clock signal of the clock receiving circuit 104 is a clock signal that the clock receiving circuit 104 generates independent or without receipt of the input clock signal CLKIN, or is a clock signal that the clock receiving circuit 104 generates dependent on or in response to receipt of the internal clock signal CLKIN.

An internal circuit component of the clock receiving circuit 104 may be configured to accurately or correctly perform its action or function in response to receipt of a clock signal having a duty cycle at a target duty cycle level. An example target duty cycle level is 50%, although other target duty cycle levels may be possible. The farther away that the duty cycle is from the target duty cycle level, the greater the likelihood that the internal circuit component will perform its action or function incorrectly, or the greater amount of errors with which the internal circuit component will perform its action or function.

For example, during a data-in operation, the farther away that the duty cycle of the input clock signal CLKIN is from the target duty cycle level, the higher the error rate the clock receiving circuit 104 will have when identifying or sampling the voltage levels or data values of the data signals DQ. Additionally, during a data-out operation, the farther away that the duty cycle of the input clock signal CLKIN is from the target duty cycle level, the more errors the clock receiving circuit 104 will make when generating data signals DQ having data pulses at incorrect voltage levels, and/or the farther away that the duty cycle of the output clock signal CLKOUT will be from the target duty cycle level. Accordingly, in order to minimize the amount of errors during data-in and data-out operations, it is desirable for the clock receiving circuit 104 to perform its operations using clock signals and/or to generate clock signals having duty cycles as close to the target duty cycle level as possible.

In general, a clock signal that has a duty cycle different than the target duty cycle level has duty cycle distortion or a distorted duty cycle. An amount that the duty cycle of the clock signal is away or different from the target duty cycle level is referred to as an amount of duty cycle distortion or an amount of duty cycle error. The duty cycle of a clock signal may be an instantaneous value that indicates a single duty cycle level of a single cycle or period of the clock signal. Alternatively, the duty cycle of a clock signal may be an average value that indicates an average duty cycle of or over a plurality of cycles or periods of the clock signal. Accordingly, an amount of duty cycle distortion may be an instantaneous value for a single cycle or period of a clock signal, or may be an average value for a plurality of cycles of periods of a clock signal.

Ideally, the clock receiving circuit 104 receives the input clock signal CLKIN, generates internal clock signals, and/or generates an output clock signal CLKOUT having a duty cycle at the target duty cycle level. However, in actual implementation, the clock receiving circuit 104 may receive the input clock signal CLK having duty cycle distortion, and/or may generate internal clock signals or an output clock signal CLKOUT with duty cycle distortion. Various reasons may exist for the duty cycle distortion, such as imperfections in the clock sending circuit 102, process-voltage-temperature (PVT) variations, or interference in the communications bus 106, as non-limiting examples. Whatever the cause may be, the clock receiving circuit 104 may include a duty cycle correction circuit that reduces duty cycle distortion in the clock signals it receives or generates.

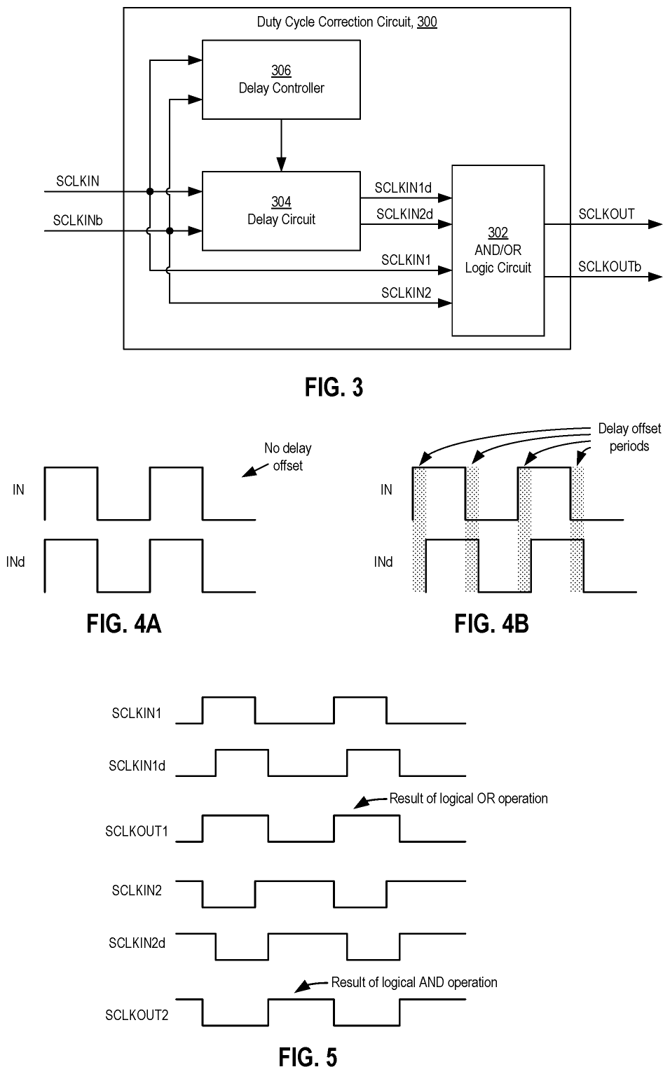

FIG. 3 shows a block diagram of an example duty cycle correction circuit 300 that may be implemented in the clock receiving circuit 104 of FIG. 1. In general, the duty cycle correction circuit 300 is configured to correct for duty cycle distortion in a pair of input sample clock signals, including a first input sample clock signal SCLKIN1 and a second input sample clock signal SCLKIN2. In some embodiments, the pair of input sample clock signals SCLKIN1, SCLKIN2 are complementary to each other, referred to as complementary input sample clock signals SCLKIN1, SCLKIN2. Also, the input sample clock signals SCLKIN1, SCLKCIN2 are referred to as input signals in that they are the signals that the duty cycle correction circuit 300 receives to perform duty cycle correction. Further, the input sample clock signals SCLKIN1, SCLKIN2 are referred to as sample signals in that, in various embodiments, they may be any of various signals that the clock receiving circuit 104 receives or generates. For example, in various embodiments, the first input sample clock signal SCLKIN1 may be the input clock signal CLKIN that the clock receiving circuit 104 receives from the clock sending circuit 102, or may be an internal clock signal that an internal circuit component of the clock receiving circuit 104 generates and outputs to the duty cycle correction circuit 300. Similarly, the second input sample clock signal SCLKIN2 can be another input clock signal that the clock receiving circuit 104 receives from the clock sending circuit 102, or an internal clock signal that an internal circuit generates and outputs to the duty cycle correction circuit 300.

Also, as used herein, duty cycle correction is an electronic process that corrects for and/or reduces duty cycle distortion in an input signal received by a duty cycle correction circuit. The duty cycle correction circuit reduces duty cycle distortion by generating an output clock signal in response to receipt of the input clock signal, where the output clock signal has a duty cycle that is closer to a target duty cycle level that the duty cycle level of the input clock signal. Optimally, the duty cycle correction circuit generates the output clock signal with a duty cycle at the target duty cycle level.

With respect to FIG. 3, the duty cycle correction circuit 300 is configured to perform duty cycle correction on each of the input sample clock signals SCLKIN1, SCLKIN2, and in response, generate a pair of output sample clock signals SCLKOUT1, SCLKOUT. In some embodiments, the pair of output sample clock signals SCLKOUT1, SCLKOUT2 are complementary to each other, referred to as complementary output sample clock signals SCLKOUT1, SCLKOUT2. Also, the output sample clock signals SCLKOUT1, SCLKOUT2 are referred to as output signals in that they are the signals that the duty cycle correction circuit 300 outputs in response to performing duty cycle correction. In the event that the input sample clock signals SCLKIN1, SCLKIN2 have duty cycle distortion, the duty cycle correction circuit 300 generates the output sample clock signals SCLKOUT1, SCLKOUT2 with a lower amount of duty cycle distortion, optimally with duty cycles at the target duty cycle level. Further, the output sample clock signals SCLKOUT1, SCLKOUT2 are referred to as sample signals in that, in various embodiments, they may be any of various signals that the clock receiving circuit 104 outputs to an internal circuit component of the clock receiving circuit 104, or may be an output clock signal that the clock receiving circuit 104 outputs externally, such as to the clock sending circuit 102.

In the example configuration shown in FIG. 3, the duty cycle correction circuit 300 includes an AND/OR logic circuit 302 that is configured to perform duty cycle correction on the input sample clock signals SCLKIN1, SCLKIN2. As used herein, an AND/OR logic circuit is a circuit that performs an AND logical operation and an OR logical operation. The AND/OR logic circuit performs an AND logical operation by generating an output signal according to AND logic, and performs an OR logical operation by generating an output signal according to OR logic.

Also, as used herein, an AND/OR logic circuit can generate an output signal according to AND logic by performing either a direct AND logical operation or an inverted AND (also referred to as a NAND) logical operation. In general, a circuit performing a direct AND logical operation on two input signals generates its output signal at a magnitude level that is a direct result of, or directly proportional to, AND logic on the two input signals. Accordingly, if both of the input signals are at respective high levels, then the circuit performing a direct AND logical operation generates its output signal at an associated high level, and if only one of the input signals is at a low level or both of the input signals are at low levels, then the circuit performing a direct AND logical operation generates its output signal at an associated low level. In addition, a circuit performing an inverted AND (or NAND) logical operation on two input signals generates its output signal at a magnitude level that is an inverted result of, or inversely proportional to, AND logic on the two input signals. Accordingly, if both of the input signals are at respective high levels, then the circuit performing an inverted AND logical operation generates its output signal at an associated low level, and if only one of the input signals is at a low level or both of the input signals are at respective low levels, then the circuit performing an inverted AND logical operation generates its output signal at an associated high level.

Also, as used herein, an AND/OR logic circuit can generate an output signal according to OR logic by performing either a direct OR logical operation or an inverted OR (also referred to as a NOR) logical operation. In general, a circuit performing a direct OR logical operation on two input signals generates its output signal at a magnitude level that is a direct result of, or directly proportional to, OR logic on the two input signals. Accordingly, if both of the input signals are at respective high levels or if only one of the input signals is at a high level, then the circuit performing a direct OR logical operation generates its output signal at an associated high level, and if both of the input signals are at low levels, then the circuit performing a direct OR logical operation generates its output signal at an associated low level. In addition, a circuit performing an inverted OR (or NOR) logical operation on two input signals generates its output signal at a magnitude level that is an inverted result of, or inversely proportional to, OR logic on the two input signals. Accordingly, if both of the input signals are at respective high levels or if only one of the input signals is at a high level, then the circuit performing an inverted OR logical operation generates its output signal at an associated low level, and if both of the input signals are at respective low levels, then the circuit performing an inverted OR logical operation generates its output signal at an associated high level.

In the example configuration shown in FIG. 3, the AND/OR logic circuit 302 is configured to generate the first output sample clock signal SCLKOUT1 according to OR logic on a first pair of sample clock signals, and the second output clock signal SCLKOUT2 according to AND logic on a second pair of sample clock signals. The first pair of sample clock signals includes the first input sample clock signal SCLKIN1 and a delayed first input sample clock signal SCLKIN1d. The second pair of sample clock signals includes the second input sample clock signal SCLKIN2 and a delayed second input sample clock signal SCLKIN2d.

In general, a delayed signal of a reference signal is a signal that has a sequence of pulses that are each temporally delayed with respect to corresponding pulses of the reference signal. With respect to the reference signal, each pulse of the sequence of pulses has a relative temporal position in the sequence relative to the other pulses. Assuming that the sequence of pulses propagates over a given point of a conductive path, the relative temporal positions of the pulses indicates when the pulses propagate over the given point relative to when the other pulses propagate over the given point. Like the reference signal, the delayed signal also has a sequence of pulses, with each pulse having a relative temporal position in the sequence relative to the other pulses. Each pulse of the delayed signal propagates over the point at a later point in time, equal to a delay amount, compared to a pulse of the reference signal that has the same temporal position in its sequence as the temporal position of pulse of the delayed signal.

Collectively, the first input sample clock signal SCLKIN1 and the delayed first input sample clock signal SCLKIN1d are referred to as a first pair of delayed input sample clock signals SCLKIN1, SCLKIN1d, and the second input sample clock signal SCLKIN2 and the delayed second input sample clock signal SCLKIN2d are referred to as a second pair of delayed input sample clock signals SCLKIN2, SCLKIN2d. Additionally, for example configurations where the first and second input sample clock signals SCLKIN1, SCLKIN2 form a pair of complementary input clock signals, the delayed input sample clock signals SCLKIN1d, SCLKIN2d also form a pair of complementary input clock signals, with the delayed second input sample clock signal SCLKIN2d referred to as a complementary delayed input clock signal.

The duty cycle correction circuit 300 may further include a delay circuit 304 that is configured to generate the delayed input sample clock signals, including a first delayed input sample clock signal SCLKIN1d and a second delayed input sample clock signal SCLKIN2d, in response to receipt of the input sample clock signals SCLKIN1, SCLKIN2. The delay circuit 304 includes input terminals at which the delay circuit 304 receives the sample input clock signals SCLKIN1, SCLKIN2, and output terminals at which the delay circuit 304 generates the delayed input sample clock signals SCLKIN1d, SCLKIN2d.

In addition, the delay circuit 304 is configured with a delay amount, which is the amount by which the delay circuit 304 delays the sample input clock signals SCLKIN1, SCLKIN2 to generate the delayed input sample clock signals SCLKIN1d, SCLKIN2d at its output terminals. Accordingly, the delay circuit 304 generates the delayed input sample clock signals SCLKIN1d, SCLKIN2d at its output terminals by delaying each of the pulses of the input sample clock signals SCLKIN1, SCLKIN2 by a delay amount. As a result, for each of the pulses of the delayed signal, a time at which the delay circuit generates a given pulse of the delayed signal at the output terminal occurs later in time, equal in duration to the delay amount, from the time that the delay circuit received the pulse of the input signal having the same temporal position in its sequence as the given pulse of the delayed signal.

The delay circuit 304 may be configured in any of various ways to delay the input sample clock signals SCLKIN1, SCLKIN2 in order to generate the delayed input sample clock signals SCLKIN1d, SCLKIN2d. For some example configurations, the delay circuit 304 may include a pair of delay chains, with each chain configured to receive and delay a respective one of the input sample clock signals SCLKIN1, SCLKIN2 to generate a respective one of the delayed input sample clock signals SCLKIN1d, SCLKIN2d. Each delay chain may include a plurality of delays cells, each having a respective delay unit. The delay amount that a delay chain has may be equal to the delay unit times the number of delay cells. Each delay cell may be in the form of an inverter or a buffer, as non-limiting examples. Various other ways of configuring the delay circuit 304 may be possible.

In addition, in at least some example configurations, the delay circuit 304 may be an adjustable delay circuit. As used herein, an adjustable delay circuit is a delay circuit that is configured to vary or adjust the delay amount by which it delays an input signal to generate a delayed, output signal. Accordingly, at different points in time, an adjustable delay circuit can delay the input signal by different delay amounts or the same delay amount. The delay circuit 304 may be configured to adjust the delay amount within a range extending from a minimum delay amount to a maximum delay amount. The minimum delay amount is the smallest amount by which the delay circuit 304 can delay the first and second input sample clock signals SCLKIN1, SCLKIN2. The maximum delay amount is the largest amount by which the delay circuit 304 is configured to delay the first and second input sample clock signals SCLKIN1, SCLKIN2.

In at least some example configurations, the minimum delay amount may be zero or sufficiently close to zero such that the delayed first input sample clock signal SCLKIN1d performs its rising and falling transitions at about the same time that the first input sample clock signal SCLKIN1 performs its corresponding rising and falling transitions, and the delayed second input sample clock signal SCLKIN2d performs its rising and falling transitions at about the same time that the second input sample clock signal SCLKIN2 performs its corresponding rising and falling transitions. As used herein, for a given pair of a signal and a delayed signal, where the delayed signal performs its rising and falling transitions at or about the same time that the signal performs its corresponding rising and falling transitions, the delayed signal is referred to as having no or zero delay offset relative to the signal, and/or referred to as performing its rising and falling transitions without a delay offset.

FIG. 4A is a timing diagram illustrating an example input signal IN and a delayed input signal INd that does not have a delay offset relative to the input signal IN. The example signal IN, INd may be a representative of the first pair of delayed input sample clock signals SCLKIN1, SCLKIN1d, and/or the second pair of delayed input sample clock signals SCLKIN2, SCLKIN2d. As shown in FIG. 4A, the input signal IN and the delayed input signal INd perform respective rising transitions at or about the same time, and perform respective falling transitions at or about the same time.

Additionally, when the delay circuit 304 increases the delay amount to a non-zero value higher than the minimum delay amount, the delayed first input sample clock signal SCLKIN1d performs its rising and falling transitions at later times than the first input sample clock signal SCLKIN1 performs its corresponding rising and falling transitions, and the delayed second input sample clock signal SCLKIN2d performs its rising and falling transitions at later times than the second input sample clock signal SCLKIN2 performs its corresponding rising and falling transitions, equal in duration to the non-zero value. As used herein, for a given pair of a signal and a delayed signal, where the delayed signal performs its rising and falling transitions at later times than the signal performs its corresponding rising and falling transitions, the delayed signal is referred to as having a delay offset (or expressly, a non-zero delay offset) relative to the signal, and/or referred to as performing its rising and falling transitions with a delay offset (or expressly, with a non-zero delay offset).

FIG. 4B is a timing diagram illustrating the example input and delayed input signals IN, INd of FIG. 4A, but with the delayed input signal INd having a non-zero delay offset relative to the input signal IN. As shown in FIG. 4B, the non-zero delay offset creates delay offset periods between the input signal IN and the delayed input signal INd. As used herein, a delay offset period, for a pair of signals including a signal and a delayed signal, is a time period extending from the time that the signal performs a transition to the time that the delayed signal performs its corresponding transition. The two corresponding transitions between which a delay offset period extends are of the same type, meaning that the two corresponding transitions are both rising transitions or are both falling transitions. Accordingly, a delay offset period extends from a rising transition of the signal to a rising transition of the delayed signal, or from a falling transition of the signal to a falling transition of the delayed signal. The amount of the delay offset period may be equal to the delay amount by which the delay circuit delays the signal to generate the delayed signal. FIG. 4B illustrates four delay offset periods created by a non-zero delay offset between the input signal IN and the delayed input signal INd, two between respective rising transitions and two between respective falling transitions.

Referring back to FIG. 3, the duty cycle correction circuit 300 may further include a delay controller (or a delay control circuit) 306 that is configured to control the delay circuit 304. Through its control, the delay controller 306 is configured to set and/or adjust the delay amounts by which the delay circuit 304 delays the sample input clock signals SCLKIN1, SCLKIN2. In various embodiments, the delay controller 306 may comprise hardware, firmware (or software), or a combination of hardware and firmware (or software). For example, a delay controller may include or be a component of an integrated circuit (IC), such as an application specific integrated circuit (ASIC) or a field programmable gate array (FPGA), a circuit, a digital logic circuit, an analog circuit, a combination of discrete circuits, gates, or any other type of hardware or combination thereof In addition, or alternatively, a delay controller may include memory hardware that comprises instructions executable with a processor or processor circuitry to implement one or more of the features of the delay controller. A delay controller, which may be an on-die NAND program controller in certain embodiments, can take the form of processing circuitry, a microprocessor or processor, and a computer-readable medium (e.g., a non-transitory computer readable storage medium) that stores computer-readable program code (e.g., software or firmware) executable by the (micro)processor, logic gates, switches, an application specific integrated circuit (ASIC), a programmable logic controller, and an embedded microcontroller.

As explained in more detail with respect to FIG. 5, the AND/OR logic circuit 302 is configured to correct for duty cycle distortion by performing an OR logical operation on the first pair of delayed input sample clock signals SCLKIN1, SCLKIN1d, and by performing an AND logical operation on the second pair of delayed input sample clock signals SCLKIN2, SCLKIN2d. The delay amount between the first pair of delayed input sample clock signals SCLKIN1, SCLKIN1d, and between the second pair of delayed input sample clock signals SCLKIN2, SCLKIN2d may determine and/or affect how much the AND/OR logic circuit 302 adjusts the duty cycles of the input sample clock signals SCLKIN1, SCLKIN2 to generate the output sample clock signals SCLKOUT1, SCLKOUT2. Accordingly, the delay controller 306 may be configured to detect or determine the amount of duty cycle distortion in the input sample clock signals SCLKIN1, SCLKIN2, and set and/or adjust the delay of the delay circuit 304 to a delay amount dependent on and/or corresponding to the amount of duty cycle distortion. In various embodiments, the delay controller 306 may receive one or both of the input sample clock signals SCLKIN1, SCLKIN2 to determine an amount of duty cycle distortion.

FIG. 5 shows the AND/OR logic circuit 302 performing duty cycle correction through illustration of timing diagrams of example magnitude waveforms of the first pair of delayed input sample clock signals SCLKIN1, SCLKIN1d, the first output sample clock signal SCLKOUT1 generated according to OR logic on the first pair of delayed input sample clock signals SCLKIN1, SCLKINd, the second pair of delayed input sample clock signals SCLKIN2, SCLKIN2d, and the second output sample clock signal SCLKOUT2 generated according to AND logic on the second pair of delayed input sample clock signals SCLKIN2, SCLKIN2d. FIG. 5 shows the first and second input sample clock signals SCLKIN1, SCLKIN2 as a pair of complementary clock signals. Additionally, FIG. 5 shows the first and second input sample clock signals SCLKIN1, SCLKIN2 each with duty cycle distortion relative to a target duty cycle level of 50%. In particular, the first input sample clock signal SCLKIN1 is at its high level for a shorter duration than it is at its low level, indicating a duty cycle lower than the target duty cycle level. Additionally, the second input sample clock signal SCLKIN2 is at its high level for a longer duration that it is at its low level, indicating a duty cycle higher than the target duty cycle level.

FIG. 5 illustrates that performing an OR logical operation on the first pair of delayed input sample clock signals SCLKIN1, SCLKIN1d reduces duty cycle distortion by generating the first output sample clock signal SCLKOUT1 to be at its high level for a longer time duration than the first input sample clock signal SCLKIN1 is at its high level, in effect moving the duty cycle of the first input sample clock signal SCLKIN1 closer to the target duty cycle level of 50%. In addition, FIG. 5 illustrates that performing an AND logical operation on the second pair of delayed input sample clock signals SCLKIN2, SCLKIN2d reduces duty cycle distortion by generating the second output sample clock signal SCLKOUT2 to be at its high level for a shorter time duration than the second input sample clock signal SCLKIN2 is at its high level, in effect moving the duty cycle of the second input sample clock signal SCLKIN2 closer to the target duty cycle level of 50%. As previously described, the delay controller 306 may be configured to set the delay amount by which to delay the input sample clock signals SCLKIN1, SCLKIN2 based on the amount of duty cycle distortion in order to cause the AND/OR logic circuit 302 to generate the output sample clock signals SCLKOUT1, SCLKOUT2 with reduced or minimized duty cycle distortion.

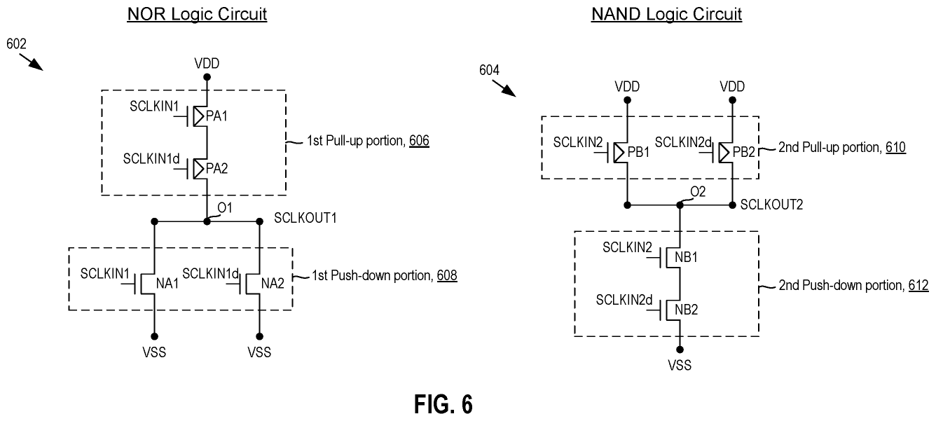

FIG. 6 shows a circuit diagram of an example configuration of the AND/OR logic circuit 302 of FIG. 3. The example configuration includes a NOR logic circuit 602 and a NAND logic circuit 604. A NOR logic circuit is a circuit that performs NOR logical operations in response to receipt of a pair of input signals. A NAND logic circuit is a circuit that performs NAND logical operations in response to a pair of input signals. The NOR logic circuit 602 is configured to receive the first pair of delayed input sample clock signals SCLKIN1, SCLKIN1d, and perform an inverted OR (or NOR) logical operation to generate the first output sample clock signal SCLKOUT1. The NAND logic circuit 604 is configured to receive the second pair of delayed input sample clock signals SCLKIN2, SCLKIN2d, and perform an inverted AND (or NAND) logical operation to generate the second output sample clock signal SCLKOUT2.

As shown in FIG. 6, the NOR logic circuit 602 and the NAND logic circuit 604 are each configured as a push-pull circuit. In general, a push-pull circuit is a circuit that generates an output signal at an output node by pulling up a magnitude (such as a voltage) of the output signal to an associated high level and by pushing down the magnitude of the output signal to an associated low level. The push-pull circuit includes two circuit portions coupled to the output node, including a pull-up portion that pulls up the magnitude to the associated high level and a push-down portion that pushes down the magnitude to the associated low level. For particular example configurations, such as the ones shown in FIG. 6, the pull-up portions include p-channel metal-oxide semiconductor field effect (PMOS) transistors, and the push-down portions include n-channel metal-oxide semiconductor field effect (NMOS) transistors.

The NOR logic circuit 602 includes a first pull-up portion 606 and a first push-down portion 608 each coupled to a first output node O1, where the NOR logic circuit 602 generates the first output sample clock signal SCLKOUT1. The first pull-up portion 606 and the first push-down portion 608 are each configured to receive the first pair of delayed input sample clock signals SCLKIN1, SCLKIN1d. Additionally, the first pull-up portion 606 includes a pair of series-connected PMOS transistors PA1, PA2, including a first PMOS transistor PA1 configured to receive the first input sample clock signal SCLKIN1 at its gate terminal, and a second PMOS transistor PA2 configured to receive the delayed first input sample clock signal SCLKIN1d at its gate terminal. Additionally, the first PMOS transistor PA1 has its source terminal coupled to a high voltage node VDD biased with a voltage at a high level VDD, the first PMOS transistor PA1 has its drain terminal coupled to the source terminal of the second PMOS transistor PA2, and the drain terminal of the second PMOS transistor PA2 is coupled to the first output node O1.

In addition, the first push-down portion 608 includes a pair of parallel-connected NMOS transistors NA1, NA2, including a first NMOS transistor NA1 configured to receive the first input sample clock signal SCLKIN1 at its gate terminal, and a second NMOS transistor NA2 configured to receive the delayed first input sample clock signal SCLKIN1d at its gate terminal. Additionally, the first and second NMOS transistors NA1, NA2 each have their drain terminals coupled to the first output node O1, and their source terminals coupled to a low voltage node VSS biased with a voltage at a low level V_{SS}. In some example configurations, the low voltage node VSS is a ground reference GND biased with a ground reference voltage VGND. The first pull-up portion 606 configured as a pair of series-connected transistors, in combination with the first push-down portion 608 configured as a pair of parallel-connected transistors, configures the push-pull circuit 602 to perform a NOR logical operation in response to receipt of the first pair of delayed input sample clock signals SCLKIN1, SCLKIN1d.

In addition, the NAND logic circuit 604 includes a second pull-up portion 610 and a second push-down portion 612 each coupled to a second output node O2, where the NAND logic circuit 604 generates the second output sample clock signal SCLKOUT2. The second pull-up portion 610 and the second push-down portion 612 are each configured to receive the second pair of delayed input sample clock signals SCLKIN2, SCLKIN2d.

As shown in FIG. 6, the NAND logic circuits pull-up and push-down portions 610, 612 have opposite series and parallel configurations compared to those of the NOR logic circuit 602. In particular, the second pull-up portion 610 includes a pair of parallel-connected PMOS transistors PB1, PB2, including a first PMOS transistor PB1 configured to receive the second input sample clock signal SCLKIN2 at its gate terminal, and a second PMOS transistor PB2 configured to receive the delayed second input sample clock signal SCLKIN2d at its gate terminal. Additionally, the first and second PMOS transistors PB1, PB2 each have their source terminals coupled to the high voltage node VDD, and their drain terminals coupled to a second output node O2.

Additionally, the second push-down portion 612 includes a pair of series-connected NMOS transistors NB1, NB2, including a first NMOS transistor NB1 configured to receive the second input sample clock signal SCLKIN2 at its gate terminal, and a second NMOS transistor NB2 configured to receive the delayed second input sample clock signal SCLKIN2d at its gate terminal. Additionally, the first NMOS transistor NB1 has its drain terminal coupled to second output node O2, the first NMOS transistor NB1 has its source terminal coupled to the drain terminal of the second NMOS transistor NB2, and the source terminal of the second NMOS transistor NB2 is coupled to the low voltage node VSS. The second pull-up portion 610 configured as a pair of parallel-connected transistors, in combination with the second push-down portion 612 configured as a pair of series-connected transistors, configures the push-pull circuit 604 to perform a NAND logical operation in response to receipt of the second pair of delayed input sample clock signals SCLKIN2, SCLKIN2d.

In addition, the PMOS and NMOS transistors of the NOR and NAND logic circuits 602, 604 may form transistor branches. In general, a transistor branch is an electrical path for current flow that includes at least one transistor. The PMOS or NMOS transistor(s) included in a transistor branch may have their drain and source terminals part of or coupled to the branch. Current flowing through the transistor branch may flow between the drain and source terminals. With respect to the NOR logic circuit 602, the series-connected PMOS transistors PA1, PA2 of the first pull-up portion 606 form a single transistor branch between the high voltage node VDD and the first output node O1. The parallel-connected NMOS transistors NA1, NA2 of the first push-down portion 608 form two parallel transistor branches between the first output node O1 and the low voltage node VSS. With respect to the NAND logic circuit 604, the parallel-connected PMOS transistors PB1, PB2 of the second pull-up portion 610 form two parallel transistor branches between the high voltage node VDD and the second output node O2. Additionally, the series-connected NMOS transistors NB1, NB2 of the second push-down portion 612 form a single transistor branch between the second output node O2 and the low voltage node VSS.

The NAND logic circuit 602 and the NOR logic circuit 604 may have associated drive strengths. In general, as used herein, a drive strength is a measure of an ability or strength of a circuit to move or transition a characteristic of a signal from an initial value to a target value. Example characteristics of a signal may include magnitude (e.g., voltage magnitude or current magnitude), amplitude, common mode (or average) voltage level, duty cycle, frequency, or pulse width, as non-limiting examples. In general, the stronger or greater the drive strength, the faster the circuit moves the characteristic from the initial value to the target value. The weaker or lower the drive strength, the slower the circuit moves the characteristic from the initial value to the target value.

Additionally, for circuits including PMOS and NMOS transistors, the drive strength of a circuit may directly correspond to, and/or be directly proportional to, an overall or effective gate width of the transistors forming the circuit. In general, combining or connecting transistors in parallel has the effect of increasing the effective gate width of the circuit, which in turn increases the drive strength of the circuit. Accordingly, a parallel combination of transistors has a larger effective gate width and drive strength compared to any single one of the transistors. To illustrate, a combination of two parallel-connected transistors having the same gate width has twice the effective gate width, and in turn twice drive strength, as one of the transistors. On the other hand, combining or connecting transistors in series has the effect of decreasing the effective gate width of the circuit, which in turn decreases the drive strength of the circuit. Accordingly, a series combination of transistors has a smaller effective gate width and drive strength compared to any single one of the transistors. To illustrate, a combination of two series-connected transistors having the same gate width has half the effective gate width, and in turn half the drive strength, as one of the transistors.

Further, the effective gate widths and drive strengths of circuits including parallel-connected PMOS and NMOS transistors may further depend on operation times and/or transition times of the signals that cause them to move the magnitude from the initial level to the target level. A parallel combination of transistors may have a larger effective gate width and drive strength when the transistors operate to move a signal magnitude (e.g., a voltage magnitude) from the initial level to the target level together, concurrently, or in tandem. Such may be the case when input signals that the parallel combination receives transition (from high to low, or from low to high) at the same time. Additionally, a parallel combination of transistors may have the same effective gate width and drive strength when the transistors operate to move a signal magnitude from the initial level to the target level at different times, separately, or disjointedly. Such may be the case when input signals that the parallel combination receives transition (from high to low, or from low to high) at different times.

Additionally, a push-pull circuit, such as the NOR logic circuit 602 or the NAND logic circuit 604, may have two drive strengths, including a pull-up drive strength and a push-down drive strength. The pull-up drive strength may be a drive strength of the pull-up portion of the push-pull circuit, and is a measure of the pull-up portion's ability to pull up the magnitude (e.g., the voltage magnitude) of the output signal from an initial, low level to a target, high level. Additionally, the pull-up drive strength may be a measure of the ability of the push-pull circuit to pull up the magnitude of the output signal to the high level during a rising transition of the output signal. The push-down drive strength may be a drive strength of the push-down portion of the push-pull circuit, and is a measure of the push-down portion's ability to push down the magnitude (e.g., the voltage magnitude) of the output signal from an initial, high level to a target, low level. Additionally, the push-down drive strength may be a measure of the ability of the push-pull circuit to push down the magnitude of the output signal to the low level during a falling transition of the output signal.

In addition, a push-pull circuit has an associated beta ratio. In general, a beta ratio of a push-pull circuit is a ratio of push-pull circuit's pull-up drive strength to its push-down drive strength. Since the pull-up and push-down drive strengths directly correspond to and/or are directly proportional to the effective gate widths, then a beta ratio of a push-pull circuit may, additionally or alternatively, be a ratio of the effective gate width of the pull-up portion to the effective gate width of the push-down portion of the push-pull circuit.

Referring specifically to FIG. 6, the NOR logic circuit 602 and the NAND logic circuit 604 may each have an associated pull-up drive strength and an associated push-down drive strength directly corresponding and/or proportional to the effective gate widths of their pull-up and push-down portions. With respect to the NOR logic circuit 602, the pull-up drive strength of the first pull-up portion 606 directly corresponds to an effective gate width of the first and second series-connected PMOS transistors PA1, PA2. Assuming that the first and second PMOS transistors PA1 and PA2 have the same gate width, the first pull-up portion 606 has an effective gate width that is half the gate width of one of the PMOS transistors PA1, PA2, and so the pull-up drive strength of the first pull-up portion 606 directly corresponds to and/or is directly proportional to half the gate width of one of the PMOS transistors PA1, PA2.

In addition, the push-down drive strength of the first push-down portion 608 directly corresponds to an effective gate width of the first and second parallel-connected

NMOS transistors NA1, NA2. Assuming that the first and second NMOS transistors NA1, NA2 have the same gate width, the effective gate width of the first push-down portion 608 is dependent on whether the first pair of delayed input sample clock signals SCLKIN1, SCLKIN1d perform rising transitions with or without a delay offset. Specifically, the first push-down portion 608 has an effective gate width that is twice the gate width of one of the NMOS transistors NA1, NA2 when the first pair of delayed input sample clock signals SCLKIN1, SCLKIN1d perform rising transitions at different times or with a delay offset—e.g., the first delayed input sample clock signal SCLKIN1d is delayed by a delay amount such that the first delayed input sample clock signal SCLKIN1d performs rising transitions later in time by the delay amount relative to the rising transitions of the first input sample clock signal SCLKIN1. Additionally, the first push-down portion 608 has an effective gate width that is the same as the gate width of one of the NMOS transistors NA1, NA2 when the first pair of delayed input sample clock signals SCLKIN1, SCLKIN1d perform rising transitions at the same time or without a delay offset—e.g., the first delayed input sample clock signal SCLKIN1d is not delayed by a delay amount (or the delay amount is zero or sufficiently close to zero so as to be negligible with respect to effective gate width and drive strength) such that the first pair of delayed input sample clock signals SCLKIN1, SCLKIN1d perform rising transitions at the same time or without a delay offset. Accordingly, the first push-down portion 608 has a push-down drive strength that directly corresponds to and/or is directly proportional to twice the gate width of one of the NMOS transistors NA1, NA2 when the first pair of delayed input sample clock signals SCLKIN1, SCLKIN1d perform rising transitions with a delay offset, and that directly corresponds to and/or is directly proportional to the gate width of one of the NMOS transistors NA1, NA2 when the first pair of delayed input sample clock signals SCLKIN1, SCLKIN1d perform rising transitions without a delay offset.

With respect to the NAND logic circuit 604, the pull-up drive strength of the second pull-up portion 610 directly corresponds to an effective gate width of the first and second parallel-connected PMOS transistors PB1, PB2. Assuming that the first and second PMOS transistors PB1, PB2 have the same gate width, the effective gate width of the second pull-up portion 610 is dependent on whether the second pair of delayed input sample clock signals SCLKIN2, SCLKIN2d perform falling transitions with or without a delay offset. Specifically, the second pull-up portion 610 has an effective gate width that is twice the gate width of one of the PMOS transistors PB1, PB2 when the second pair of delayed input sample clock signals SCLKIN2, SCLKIN2d perform falling transitions at different times—e.g., the second delayed input sample clock signal SCLKIN2d is delayed by a delay amount such that the second delayed input sample clock signal SCLKIN2d performs falling transitions later in time by the delay amount relative to the falling transitions of the second input sample clock signal SCLKIN2. Additionally, the second pull-up portion 610 has an effective gate width that is the same as the gate width of one of the PMOS transistors PB1, PB2 when the second pair of delayed input sample clock signals SCLKIN2, SCLKIN2d perform falling transitions at the same time—e.g., the second delayed input sample clock signal SCLKIN2d is not delayed by a delay amount (or the delay amount is zero or sufficiently close to zero so as to be negligible with respect to effective gate width and drive strength) such that the second pair of delayed input sample clock signals SCLKIN2, SCLKIN2d perform falling transitions at the same time. Accordingly, the second pull-up portion 610 has a pull-up drive strength that directly corresponds to and/or is directly proportional to twice the gate width of one of the PMOS transistors PB1, PB2 when the second pair of delayed input sample clock signals SCLKIN2, SCLKIN2d perform rising transitions with a delay offset, and that directly corresponds to and/or is directly proportional to the gate width of one of the PMOS transistors PB1, PB2 when the second pair of delayed input sample clock signals SCLKIN2, SCLKIN2d perform falling transitions without a delay offset.

Additionally, the push-down drive strength of the second push-down portion 612 directly corresponds to an effective gate width of the first and second series-connected NMOS transistors NB1, NB2. Assuming that the first and second NMOS transistors NB1 and NB2 have the same gate width, the second push-down portion 612 has an effective gate width that is half the gate width of one of the NMOS transistors NB1, NB2, and so the push-down drive strength of the second push-down portion 612 directly corresponds to and/or is proportional to half the gate width of one of the NMOS transistors NB1, NB2.

In various embodiments, the NOR logic circuit 602 and the NAND logic circuit 604 are configured to have the same or matching beta ratios, dependent on the first and second pairs of delayed input sample signals SCLKIN1, SCLKIN1d and SCLKIN2, SCLKIN2d each having non-zero delay offsets. To do so, each of the PMOS and NMOS transistors may have a gate width that is a certain multiple of a gate width unit w that provides a predetermined beta ratio.

As an example illustration, the NOR logic circuit 602 and the NAND logic circuit 604 may each be configured to have a predetermined beta ratio of two to-one (2:1). To do so, with respect to the NOR logic circuit 602, each of the PMOS transistors PA1, PA2 may have a gate width of 4*w to provide an effective gate width of 2*w, and each of the NMOS transistors NA1, NA2 may have a gate width of 1*w to provide an effective gate width of 1*w, yielding a beta ratio of two-to-one (2:1). With respect to the NAND logic circuit 604, each of the PMOS transistors PB1, PB2 may have a gate width of 2*w to provide an effective gate width of 2*w, and each of the NMOS transistors NB1, NB2 may have a gate width of 2*w to provide an effective gate width of w, yielding the same or matching beta ratio of two-to-one (2:1).

However, during duty cycle correction, the delay controller 306 may determine to minimize the delay amount for optimal performance, causing the first and second pairs of delayed input sample clock signals SCLKIN1, SCLKIN1d and SCLKIN2, SCLKIN2d without a delayed offset (or with minimal delay offset), which in turn changes the beta ratios of the NOR and NAND logic circuits 602, 604 such that they no longer match. For example, using the previous example illustration, when the first delayed input sample clock signals SCLKIN1, SCLKIN1d transition together, the effective gate width of the first push-down portion 608 changes to 2*w, changing the beta ratio of the NOR logic circuit 602 from two-to-one (2:1) to one-to-one (1:1). In addition, when the second delayed input sample clock signals SCLKIN2, SCLKIN2d transition together, the effective gate width of the second pull-up portion 610 changes to 4*w, changing the beta ratio of the NAND logic circuit 604 from two-to-one (2:1) to four-to-one (4:1). The beta ratio mismatch between the NOR and NAND logic circuits 602, 604 may cause duty cycle degradation—i.e., cause the NOR logic circuit 602 and/or the NAND logic circuit 604 to generate one or both of the output sample clock signals SCLKOUT1, SCLKOUT2 with duty cycle distortion. Effectively, during duty cycle correction, the AND/OR logic circuit 302 having the configuration of FIG. 6 and the delay controller 306 may undesirably work against each other, with the delay controller 306 setting a delay amount for duty cycle correction that causes the AND/OR logic circuit 302 to introduce duty cycle distortion when generating the output sample clock signals SCLKOUT1, SCLKOUT2.

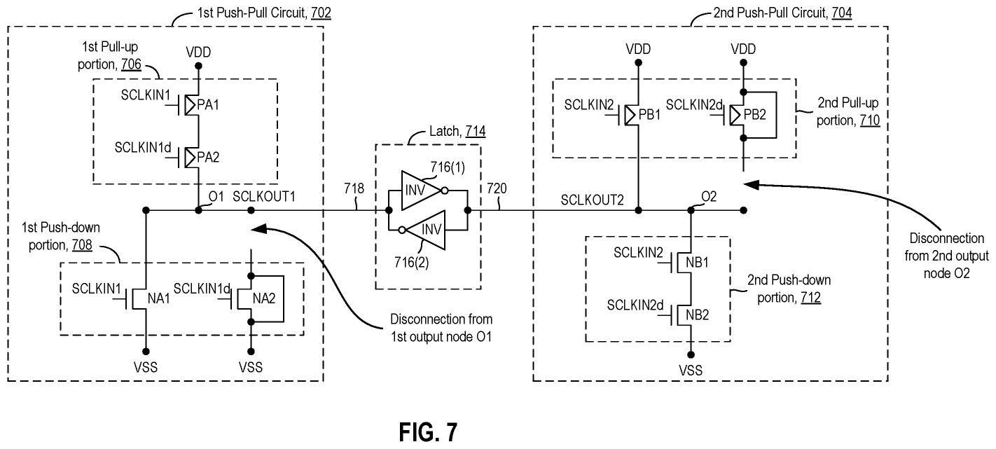

FIG. 7 shows a partial circuit diagram of another example configuration of the AND/OR logic circuit 302 of FIG. 3. The example configuration of FIG. 7 includes two push-pull circuits, including a first push-pull circuit 702 and second push-pull circuit 704. The first push-pull circuit 702 is configured to generate the first output sample clock signal CLKOUT1 at a first output node O1, and the second push-pull circuit 704 is configured to generate the second output sample SCLKOUT2 at a second output node O2.

Similar to the NOR logic circuit 602 in FIG. 6, the first push-pull circuit 702 includes a first pull-up portion 706 and a first push-down portion 708, each coupled to the first output node O1. The first pull-up portion 706 includes two series connected PMOS transistors PA1, PA2 configured to receive the first pair of delayed input sample clock signals SCLKIN1, SCLKIN1d. Additionally, the first PMOS transistor PA1 has its source terminal coupled to a high voltage node VDD biased with a high voltage VDD, its drain terminal coupled to the source terminal of the second PMOS transistor PA2, and the drain terminal of the second PMOS transistor PA2 coupled to the first output node O1.

Unlike the NOR logic circuit 502, the first push-down portion 708 in FIG. 7 includes a single transistor branch, comprising an NMOS transistor NA1, coupled to the first output node O1. Otherwise stated, the first push-down portion 708 includes a single NMOS transistor NA1, rather than a pair of parallel-connected NMOS transistors NA1, NA2, to pull down the voltage of the first output sample clock signal SCLKOUT1 to the low level V_{SS}. The single transistor branch eliminates the dependency that the effective gate width and push-down drive strength of first push-down portion 708 have on the timing of transitions of the first pair of delayed input sample clock signals SCLKIN1, SCLKIN1d. Accordingly, the first push-down portion 708 is configured with a fixed or constant effective gate width and push-down drive strength irrespective or independent of whether or not the first pair of delayed input sample clock signals SCLKIN1, SCLKIN1d have a non-zero delay offset between them.

Additionally, similar to the NAND logic circuit 604 in FIG. 6, the second push-pull circuit 704 includes a second pull-up portion 710 and a second push-down portion 712, each coupled to the second output node O2. The second push-down portion 712 includes two series connected NMOS transistors NB1, NB2 configured to receive the second pair of delayed input sample clock signals SCLKIN2, SCLKIN2d. Additionally, the second NMOS transistor NB2 has its source terminal coupled to a low voltage node VSS biased with a low voltage V_{SS}, its drain terminal coupled to the source terminal of the first NMOS transistor NB1, and the drain terminal of the first NMOS transistor NB1 is coupled to the second output node O2.

Unlike the NAND logic circuit 704, the second pull-up portion 704 in FIG. 7 includes a single transistor branch, comprising a PMOS transistor PB1, coupled to the second output node O2. Otherwise stated, the second pull-up portion 710 includes a single PMOS transistor PB1, rather than a pair of parallel-connected PMOS transistors PB1, PB2, to pull up the voltage of the second output sample clock signal SCLKOUT2 to the high level VDD. The single transistor branch eliminates the dependency that the effective gate width and push-down drive strength of second pull-up portion 710 have on the timing of transitions of the second pair of delayed input sample clock signals SCLKIN2, SCLKIN2d. Accordingly, the second pull-up portion 710 is configured with a fixed or constant effective gate width and pull-up drive strength irrespective or independent of whether or not the second pair of delayed input sample clock signals SCLKIN2, SCLKIN2d have a non-zero delay offset between them.

In operation, when the first pair of delayed input sample clock signals CLKIN1, CLKIN1d transition at the same time, the first push-pull circuit 702 behaves or operates as a NOR logic circuit. However, when the first pair of delayed input sample clock signals CLKIN1, CLKIN1d have a non-zero delay offset between them, both the first pull-up and push-down portions 706, 708, and in turn the entire push-pull circuit 702, float with respect to the first output node O1 during delay offset periods determined by the non-zero delay offset. In general, a circuit floats with respect to a node where it is not operating to influence a magnitude level of a voltage or current at the node. Accordingly, a pull-up portion of a push-pull circuit floats with respect to an output node when its PMOS transistors are turned off such that it is not sourcing any current to the output node or otherwise operating to pull up the voltage at the output node to the high level. Similarly, a push-down portion of a push-pull circuit floats with respect to an output node when all of its NMOS transistors are turned off such that it is not sinking any current away from the output node or otherwise operating to push down the voltage at the output node to the low level.

During the non-delay offset periods—i.e., the time periods outside of the delay offset periods—when the delayed input sample clock signals SCLKIN1, SCLKIN1d are at different levels, the first push-pull circuit 702 operates or behaves according to NOR logic. Additionally, during the delay offset periods of the first pair of delayed input sample clock signals SCLKIN1, SCLKIN1d, both the first pull-up circuit 706 and the first push-down circuit 708 are floating with respect to the first output node O1.

Additionally, in operation, when the second pair of delayed input sample clock signals CLKIN2, CLKIN2d transition at the same time, the second push-pull circuit 702 behaves or operates as a NAND logic circuit. However, when the second pair of delayed input sample clock signals CLKIN2, CLKIN2d have a non-zero delay offset between them, both the second pull-up and push-down portions 710, 712, and in turn the entire second push-pull circuit 704, float with respect to the second output node O2 during delay offset periods determined by the non-zero delay offset. During the non-delay offset periods when the delayed input sample clock signals SCLKIN2, SCLKIN2d are at different levels, the first push-pull circuit 702 operates or behaves according to NAND logic.

The configuration in FIG. 7 may further include a latch circuit 714 coupled between the first and second push-pull circuits 702, 704 that maintains the NOR and NAND logic functionality during the delay offset periods when the first and second pull-up and push-down portions 706-712 are floating. In general, a latch circuit is a circuit that maintains a voltage at a current magnitude level until the latch circuit is triggered to change the voltage to a different level. In the example configuration of FIG. 7, the latch circuit 714 is configured as a pair of cross-coupled inverter circuits (also referred to as back-to-back inverter circuits) 716(1), 716(2). The input of the first inverter 716(1) is coupled to the output of the second inverter 716(2) at a first end 718 of the latch 714, and the output of the first inverter 716(1) is coupled to the input of the second inverter 716(2) at a second end 720 of the latch 714. The cross-coupled inverters 716(1), 716(2), or the latch 714 as a whole, are converted to maintain voltages at opposing levels at the first and second ends 718, 720.

As shown in FIG. 7, the first end 718 is coupled to the first output node O1 and the second end 720 is coupled to the second output node O2. During operation with respect to the first push-pull circuit 702, when the first pair of delayed input sample clock signals SCLKIN1, SCLKIN1d are both at their low levels, the first pull-up portion 706 is activated to pull up the voltage of the first output sample clock signal SCLKOUT1 to the high level, in accordance with NOR logic. Then, when the first input sample clock signal SCLKIN1 transitions high but the delayed first input sample clock signal SCLKIN1d remains low at the start of a delay offset period, the first pull-up portion 706 deactivates and the first push-down portion 708 activates to push down the voltage of the first output sample clock signal SCLKOUT1 to the low level, in accordance with NOR logic. At the end of the delay offset period, the delayed first input sample clock signal SCLKIN1d transitions high so that both signals SCLKIN1 and SCLKIN1d are at the high level, and the push-down portion 708 remains activated to maintain the voltage of the first output sample clock signal SCLKOUT1 at the low level, in accordance with NOR logic.

The first input sample clock signal SCLKIN1 may then transition low at the beginning of a next delay offset period. During this next delay offset period, with the first input sample clock signal SCLKIN1 at the low level and the delayed first input sample clock signal SCLKIN1d still at the high level, both the first pull-up portion 706 and the first push-down portion 708 are floating with respect to the first output node O1. During this delay period, the latch circuit 714 maintains the first output sample clock signal SCLKOUT1 at the low level, maintaining the NOR logic despite both of the first pull-up and push-down portions 706, 708 floating. Then, at the end of the delay period when the delayed first input sample clock signal SCLKIN1d transitions low, the first pull-up portion 706 activates, pulling up the voltage of the first output sample clock signal SCLKOUT1 to the high level, in accordance with NOR logic. The delayed first input sample clock signal SCLKIN1d transitioning low may serve as a trigger to the latch 714, overcoming the ability of the latch 714 to maintain the voltage of the first output sample clock signal SCLKOUT at the low level. The first push-pull circuit 702 in combination with the latch 714 may continue to operate in this manner, generating the first output sample clock signal SCLKOUT1 at high and low voltage levels according to NOR logic, over subsequent cycles or periods of the first pair of delayed input sample clock signals SCLKIN1, SCLKIN1d.

In concurrent operation with respect to the second push-pull circuit 704, when the second pair of delayed input sample clock signals SCLKIN2, SCLKIN2d are both at their high levels, the second push-down portion 712 is activated to push down the voltage of the second output sample clock signal SCLKOUT2 to the low level, in accordance with NAND logic. Then, when the second input sample clock signal SCLKIN2 transitions low but the delayed second input sample clock signal SCLKIN2d remains high at the start of a delay offset period, the second push-down portion 712 deactivates and the second pull-up portion 710 activates to pull up the voltage of the second output sample clock signal SCLKOUT2 to the high level, in accordance with NAND logic. At the end of the delay offset period, the delayed second input sample clock signal SCLKIN2d transitions low so that both signals SCLKIN2 and SCLKIN2d are at the low level, and the second pull-up portion 710 remains activated to maintain the voltage of the second output sample clock signal SCLKOUT2 at the high level, in accordance with NAND logic.

The second input sample clock signal SCLKIN2 may then transition high at the beginning of a next delay offset period. During this next delay offset period, with the second input sample clock signal SCLKIN2 at the high level and the delayed second input sample clock signal SCLKIN1d still at the low level, both the second pull-up portion 710 and the second push-down portion 712 are floating with respect to the second output node O2. During this delay period, the latch circuit 714 maintains the second output sample clock signal SCLKOUT2 at the high level, maintaining the NAND logic despite both of the second pull-up and push-down portions 710, 712 floating. Then, at the end of the delay period when the delayed second input sample clock signal SCLKIN2d transitions high, the second push-down portion 712 activates, pushing down the voltage of the second output sample clock signal SCLKOUT2 to the low level, in accordance with NAND logic. The delayed second input sample clock signal SCLKIN2d transitioning high may serve as a trigger to the latch 714, overcoming the ability of the latch 714 to maintain the voltage of the second output sample clock signal SCLKOUT at the high level. The second push-pull circuit 704 in combination with the latch 714 may continue to operate in this manner, generating the second output sample clock signal SCLKOUT2 at high and low voltage levels according to NAND logic, over subsequent cycles or periods of the second pair of delayed input sample clock signals SCLKIN2, SCLKIN2d.

In order for the first pull-up portion 706 and the second push-down portion 712 to overcome the latch 714, the drive strengths of the first pull-up portion 706 and the second push-down portion 712 may be much stronger than those of the latch 714, including the pull-up and push-down drive strengths of the inverters 716(1), 716(2). In terms of overall gate width, for some embodiments, the effective gate widths of the pull-up and push-down portions of the inverters 716(1), 716(2) may be in a range of about 0.05 to 0.5 times the effective gate width of the first pull-up portion 706 or the second push-down portion 712. In other embodiments, the effective gate widths of the pull-up and push-down portions of the inverters 716(1), 716(2) may be in a range of about 0.1 to 0.25 times the effective gate width of the first pull-up portion 706 or the second push-down portion 712.

Additionally, for at least some embodiments of the example configuration of FIG. 7, the first push-pull circuit 702 and the second push-pull circuit 704 may be configured with the same or matching beta ratios. Because the first push-down portion 708 and the second pull-up portion 710 are each configured with a constant or fixed effective gate width, independent of the amount of the delay offset in the delayed first and second input sample clock signals SCLKIN1d, SCLKIN2d, then the first and second push-pull circuits 702, 704, in combination with the latch 714, may be configured to generate the first and second output sample clock signals SCLKOUT1, SCLKOUT2 with matching beta ratios in accordance with AND and OR logical operations, independent of the amount of delay to which the delay controller 306 (FIG. 3) determines to set the delay circuit 304 in order to correct for duty cycle distortion. As such, the delay controller 306 may be configured to set the delay circuit 304 to the have minimum delay, if desirable to correct for duty cycle distortion, without the beta ratios of the AND/OR logic circuit 302 changing to different values, and without the AND/OR logic circuit 302 introducing duty cycle distortion into the output sample clock signals SCLKOUT1, SCLKOUT2, thus optimizing the ability of the duty cycle correction circuit 300 to correct for duty cycle distortion in the input sample clock signals SCLKIN1, SCLKIN2.

Additionally, for at least some example configurations, such as the one shown in FIG. 7, the first push-pull circuit 702 may be configured as a NOR logic circuit, such as by having a NOR transistor topology like the NOR logic circuit 602 of FIG. 6, but with one of its parallel transistor branches of the first push-down portion 708 disconnected from the first output node O1. In particular, as shown in FIG. 7, the first push-down portion 708 may include an additional, second parallel transistor branch comprising a second NMOS transistor NA2 that is configured to receive the delayed first input sample clock signal SCLKIN1d. However, as shown in FIG. 7, the drain terminal of the second NMOS transistor NA2 is disconnected or electrically isolated from the first output node O1 such that a current path is not formed between the first output node O1 and the low voltage node VSS. Further, as shown in FIG. 7, the second NMOS transistor NA2 may have its source and drain terminals coupled together and to the low voltage node VSS. The additional disconnected parallel transistor branch, including the second NMOS transistor NA2 may serve as dummy loading so that the first push-pull circuit 702 has matching gate loading for receipt of the first pair of delayed input clock sample signals SCLKIN1, SCLKIN1d.

Similarly, the second pull-up portion 710 may include an additional, second parallel transistor branch comprising a second PMOS transistor PB2 that is configured to receive the delayed second input sample clock signal SCLKIN2d. However, the drain terminal of the second PMOS transistor PB2 is disconnected or electrically isolated from the second output node O2 such that a current path is not formed between the high voltage node VDD and the second output node O2. Similar to the second NMOS transistor NA2, the second PMOS transistor PB2 may have its source and drain terminals coupled together and to the high voltage node VDD. The additional disconnected parallel transistor branch, including the second PMOS transistor PB2, may serve as dummy loading so that the second push-pull circuit 707 has matching gate loading for receipt of the second pair of delayed input clock sample signals SCLKIN2, SCLKIN2d.

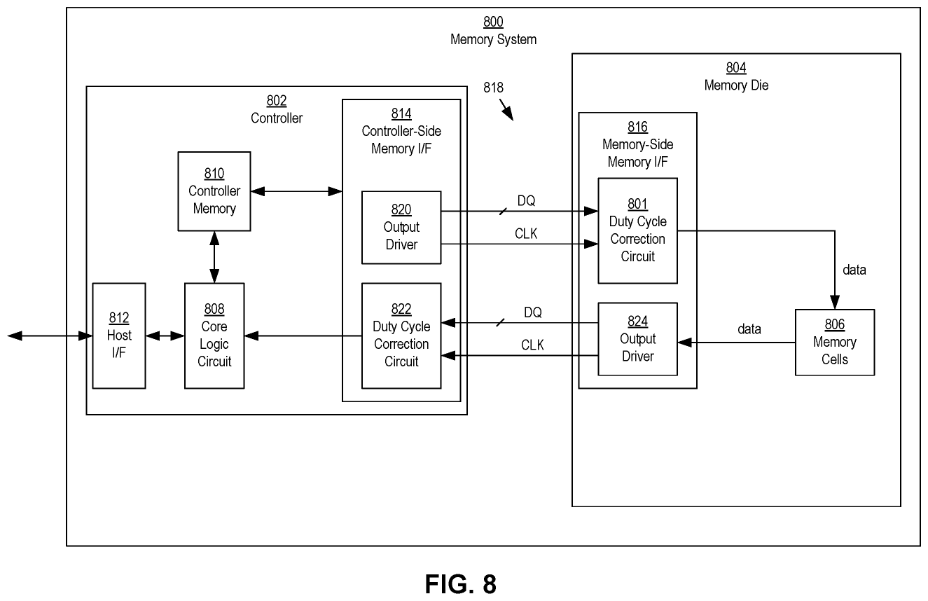

FIG. 8 shows a block diagram of an example memory system 800 that includes at least one duty cycle correction circuit or system 801 configured as the duty cycle correction circuit 300 with an AND/OR logic circuit, in accordance with the embodiments described with reference to FIGS. 3-7, and/or that is representative of example configurations of the clock sending circuit 102 and the clock receiving circuit 104 of FIG. 1. The memory system 800 may be configured to be connected to and/or in communication with a host system (not shown). The host system may be any electronic system or device that is configured to communicate and/or operate with the memory system 800.

The memory system 800 may include a controller 802 and a memory die 804. The memory die 804 may include a memory cell structure 806 of memory cells or elements, with each memory cell or element being configured to store one or more bits data. Any suitable type of memory cells can be used. As examples, the memory cells may be volatile memory such as dynamic random access memory (“DRAM”) or static random access memory (“SRAM”), non-volatile memory, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), phase-change memory (“PCM”), other elements comprising semiconductor or other material capable of storing information, or various combinations thereof. Each type of memory may have different configurations. For example, flash memory may be configured in a NAND or a NOR configuration.

The memory cells can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in they direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

The controller 802 may include a core logic circuit 808. The core logic circuit 808 may be configured to perform memory management functions, non-limiting examples of which may include, but not limited to, communicating with the host system, including receiving, handling, and responding to host requests or commands, such as read, write, erase, and status requests/commands received from the host system; error detection and correction (which may be part of handling host requests/commands); formatting the memory cells 806 to ensure it is operating properly; mapping out bad memory cells; allocating spare cells to be substituted for future failed cells; wear leveling (distributing writes to avoid wearing out specific blocks of memory that would otherwise be repeatedly written to); garbage collection (after a block is full, moving only the valid pages of data to a new block, so the full block can be erased and reused); folding operations (moving data from a lower density memory area to a higher density memory area of the memory 806); and transitioning the memory system 800 between different states, operation modes, and/or power consumption modes. In operation, when the host system needs to read data from or write data to the memory 806, it may communicate with the core logic circuit 808. The core logic circuit 808 may include hardware or a combination of hardware and software. For example, the core logic circuit 808 may include a central processing unit, an application specific integrated circuit (ASIC), a field programmable gate array (FPGA), a digital logic circuit, an analog circuit, a combination of discrete circuits, gates, or any other type of hardware, or a combination thereof.

The controller 802 may also include controller memory 810, which may include volatile memory (e.g., random access memory (RAM)), non-volatile memory (e.g., read-only memory (ROM)), or a combination thereof. The controller memory 810 may store software or firmware instructions and/or certain data structures, such as address translation data structures, that the core logic circuit 808 may access and/or and execute to perform at least some of its memory management functions. Additionally, the core logic circuit 808 may temporarily store data that is to be transferred to and stored in the memory cells 806 such as in response to a host write command, and/or that was retrieved from the memory cells 806 and is to be sent to the host system, such as in response to a host read command. FIG. 8 shows the controller memory 810 as a component of the controller 802, although in other example configurations, at least some of the controller memory 810 may be a component of the memory system 800 that is separate from the controller 802. For example, the controller 802 may be an integrated circuit, and depending on the configuration of the memory system 800, the controller memory 810 may be located on the integrated circuit, partially on the integrated circuit and partially separate from the integrated, or completely separate from the integrated circuit.

The controller 802 may further include a host interface (I/F) 812. The core logic circuit 808 may be configured to communicate with a host system via a host interface 812. In addition, the controller 802 may include a controller-side memory interface (I/F) 814 through which the controller 802 is configured to communicate with the memory die 804. Similarly, the memory die 804 may include a memory-side memory interface (I/F) 1116 through which the memory die 1104 is configured to communicate with the controller 802. As shown in FIG. 8, the memory-side memory interface 816 may include the duty cycle correction circuit or system 801, although in other example configurations, the duty cycle correction circuit 801 may be considered a component of the memory die 804 separate from the memory-side memory interface 816.

When the controller 802 wants to read data from or program data into the memory cells 806, such as in response to receipt of a host command from the host system, the controller 802 may send a clock signal CLK via communications bus 818 that connects or couples the controller-side and memory-side memory interfaces 814, 816. Where the controller 802 wants to program data, the controller 802 may also send data signals DQ carrying the data via the communications bus 818. In some example configurations, the controller-side memory interface 814 may include an output driver 820 to output the data signals DQ and the clock signal CLK. The duty cycle correction circuit 801, such as through use of AND/OR logic circuit as previously described, may correct for duty cycle distortion in the clock signal CLK received from the controller 802.

Also, as shown in FIG. 8, in some example configurations, the controller 802 may also include a duty cycle correction circuit or system 822 configured as the duty cycle correction circuit 300 with an AND/OR logic circuit 302, in accordance with the embodiments described with reference to FIGS. 3-7. FIG. 8 shows the duty cycle correction system 822 of the controller 802 as a component of the controller-side memory interface 814, although other configurations may be possible. When the controller 802 wants to read data stored in the memory cells 806, the data may be communicated to an output driver circuit 824 of the memory-side memory interface 816. The output driver 824 may transmit data signals DQ that includes the data along with a clock signal CLK. The controller 802 may use the clock pulses of the clock signal CLK to identify the logic levels of the data signals DQ. The clock signal CLK may be sent to the duty cycle correction circuit 822 of the controller 802, and the duty cycle correction circuit 822 may correct for duty cycle distortion.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the preferred embodiments described herein can be used alone or in combination with one another.

We claim:

1. A circuit comprising:
a first push-pull circuit configured to generate a first output signal in response to receipt of a first pair of input signals;
a second push-pull circuit configured to generate a second output signal in response to receipt of a second pair of input signals; and
a latch circuit coupled between the first push-pull circuit and the second push-pull circuit, the latch circuit configured to maintain magnitude levels of the first output signal and the second output signal during delay offset periods of the first pair of input signals and the second pair of input signals.

2. The circuit of claim 1, wherein the first push-pull circuit and the second push-pull circuit comprise matching beta ratios.

3. The circuit of claim 1, wherein the first push-pull circuit comprises a NOR logic circuit comprising a parallel transistor branch that is disconnected from an output node at which the first push-pull circuit generates the first output signal.

4. The circuit of claim 3, wherein the parallel transistor branch comprises an n-channel metal-oxide semiconductor field-effect transistor comprising a drain terminal and a source terminal coupled together.

5. The circuit of claim 1, wherein the second push-pull circuit comprises a NAND logic circuit comprising a parallel transistor branch that is disconnected from an output node at which the second push-pull circuit generates the second output signal.

6. The circuit of claim 5, wherein the parallel transistor branch comprises a p-channel metal-oxide semiconductor field-effect transistor comprising a drain terminal and a source terminal coupled together.

7. The circuit of claim 1, wherein the latch circuit comprises a pair of cross-coupled inverters.

8. The circuit of claim 1, wherein a first signal of the first pair of input signals and a second signal of the second pair of input signals comprise a pair of complementary signals.

9. A circuit comprising:
an AND/OR logic circuit configured to:
receive a first pair of input signals and a second pair of input signals;
generate a first signal of a pair of output signals according to AND logic on the first pair of input signals and a first beta ratio; and
generate a second signal of the pair of output signals according to OR logic on the second pair of input signals and a second beta ratio that matches the first beta ratio.

10. The circuit of claim 9, wherein the AND/OR logic circuit is further configured to maintain magnitude levels of the pair of output signals during delay offset periods of the first pair of input signals and the second pair of input signals.

11. The circuit of claim 9, wherein the AND/OR logic circuit comprises a first push-pull circuit and a second push-pull circuit that are configured to float relative to a pair of output nodes during the delay offset periods.

12. The circuit of claim 11, wherein the first push-pull circuit comprises the first beta ratio, the second push-pull circuit comprises the second beta ratio, and wherein the first beta ratio and the second beta ratio are constant values independent of a delay offset between the first pair of input signals or the second pair of input signals.

13. The circuit of claim 9, wherein the AND/OR logic circuit is configured to reduce duty cycle distortion in the first pair of input signals and the second pair of input signals in response to generation of the pair of output signals.

14. The circuit of claim 9, wherein the AND logic comprises NAND logic.

15. The circuit of claim 9, wherein the OR logic comprises NOR logic.

16. A system comprising:
a delay circuit configured to delay an input clock signal based on an amount of duty cycle distortion in the input clock signal to generate a delayed input clock signal; and
an AND/OR logic circuit comprising:
a NOR logic circuit comprising a first parallel transistor branch disconnected from a first output node, the NOR logic circuit configured to generate a first output clock signal at the first output node in response to receipt of the input clock signal and the delayed input clock signal;
a NAND logic circuit comprising a second parallel transistor branch disconnected from a second output node, the NAND logic circuit configured to generate a second output clock signal at the second output node in response to receipt of a complementary input clock signal and a complementary delayed input clock signal; and
a latch circuit connected to the first output node and to the second output node.

17. The system of claim 16, wherein the NOR logic circuit comprises a first beta ratio and the NAND logic circuit comprises a second beta ratio that matches the first beta ratio.

18. The system of claim 17, wherein the first beta ratio of the NOR logic circuit is a fixed value independent of a delay offset between the first input clock signal and the first delayed input clock signal.

19. The system of claim 17, wherein the second beta ratio of the NAND logic circuit is a fixed value independent of a delay offset between the second input clock signal and the second delayed input clock signal.

20. The system of claim 16, wherein the latch comprises a pair of cross-coupled inverters.
